(19) United States
(12) Patent Application Publication
(10) Pub. No.: US 2003/0159925 A1
(43) Pub. Date: Aug. 28, 2003

(54) Spattering device

(76) Inventor: Hiroaki Sako, Jingshu-sheng (CN)

Correspondence Address: COHEN, PONTANI, LIEBERMAN & PAVANE, 551 FIFTH AVENUE, SUITE 1210, NEW YORK, NY, 10176, US

(21) Appl. No.: 10/221,911

(22) PCT Filed: Jan. 29, 2002
(86) PCT No.: PCT/JP02/00659

(51) Int. Cl. C23C 14/34

(52) U.S. Cl. 204/298.07; 204/298.11; 204/298.08

(57) ABSTRACT

A sputtering apparatus 1 sputters a target 8 with ions in a plasma using a magnetron sputtering method, to form an ITO film from the target 8 on glass substrates 5 mounted on a rotating carousel 4. Manifolds 9 and 10, which have a shape that is symmetrical about each of two mutually orthogonal central axes in the plane of the target 8, are disposed so as to surround the whole periphery of the target 8, and process gas discharge ports 9a and 10a for discharging a process gas onto the target 8 are provided in a manner being distributed over the whole of the manifolds 9 and 10.

### TECHNICAL FIELD

The present invention relates to a sputtering apparatus, and in particular to a sputtering apparatus that manufactures a substrate having a transparent electrically conductive film for liquid crystal display apparatuses.

### BACKGROUND ART

A substrate having a transparent electrically conductive film used in a color liquid crystal display apparatus is generally manufactured by coating a color filter made of an organic resin (organic substance) onto a glass substrate, and coating a protective film also made of an organic resin onto the color filter to form a color filter substrate, and then uniformly forming an electrically conductive transparent electrode (transparent electrically conductive film) on the color filter substrate. The transparent electrically conductive film thus formed on the color filter substrate is usually formed into a desired wiring configuration by wet etching. Indium oxide doped with tin oxide (hereinafter referred to as “indium-tin oxide (ITO)”) is generally used as the material of the transparent electrically conductive film.

With the fields in which color liquid crystal display apparatuses are used expanding and the performance of color liquid crystal display apparatuses increasing dramatically, it has come to be demanded when forming an ITO film on a color filter substrate that special care is taken that the ITO film formed is of uniform thickness and quality over the whole surface of a substrate having a large area. For example, it is necessary to carry out a stable electrical discharge across the whole surface of a target having a large area, thus generating a uniform plasma while eliminating the effects of gas components discharged from the organic resin coated onto the surface of the color filter substrate.

Magnetron sputtering is the most widely used method of forming the ITO film. Magnetron sputtering is suitable for forming a thin film onto a color filter substrate having a large area, and has the advantage that by carrying out the formation of the thin film at a relatively low temperature, generation of gas components from an organic substance coated onto the substrate can be reduced.

In magnetron sputtering, with regard to technology for controlling the state of the plasma in the sputtering, technology has been proposed that focuses on the method of introducing the process gas, which plays an important role in and has a large effect on the thickness and quality of the thin film formed on the color filter substrate.

For example, in Japanese Laid-open Patent Publication (Kokai) No. 05-148627 a sputtering apparatus is proposed in which a process gas introducing port is disposed close to the cathode. According to this apparatus, because the positional relationship between the process gas introducing port and the cathode is fixed, there are effects that there is no need to consider the positional relationship between the process gas introducing port and the cathode, and adjustment of the position of the process gas introducing port after maintenance or inspection is unnecessary.

Moreover, in Japanese Laid-open Patent Publication (Kokai) No. 05-243155, a sputtering apparatus for forming a metal coating on a semiconductor substrate is proposed in which the process gas is fed in simultaneously from the periphery of a circular substrate and the periphery of a circular target, and means for exhausting the process gas fed in is provided. According to this apparatus, the process gas is distributed uniformly over the target and the substrate, and hence there are effects that the properties of the coating can be made more uniform and foreign matter can be reduced.

However, of the conventional sputtering apparatuses described above, in the case of the former, the position of introduction of the process gas is merely placed fixedly near to the cathode, and hence it is difficult to obtain a uniform gas distribution over the whole surface of a target having a large area.

Moreover, in the case of the latter, the diameters of the substrate and the target are at most about 150 to 200 mm, and hence although one would presume that it would be relatively easy to feed the process gas in uniformly over such an area, one would predict that the distribution of the process gas would not be uniform right from the peripheral part of the substrate to the central part of the substrate in the case of a substrate having a large area. Moreover, in the case of the latter apparatus, consideration is not given to the effects of gas components discharged from an organic substance coated onto the surface of a color filter substrate.

Moving on, to reduce the manufacturing cost of an ITO film, the ITO film is generally formed on a color filter substrate having a large area, which is subsequently cut to the desired size. Because the color filter and the protective film are made from an organic resin, the sputtering for forming the ITO film is carried out below the heat resistance temperature of these organic resins. The method used for forming the ITO film is thus any of various types of magnetron sputtering method capable of forming an ITO film at a relatively low temperature, as described above. In magnetron sputtering, sputtering electrical power is applied to the cathode to generate a plasma in a process gas atmosphere in a vacuum chamber by a glow discharge, and a target is sputtered by the plasma, thus forming the ITO film on the substrate.

Of the various types of magnetron sputtering, DC/RF superimposition type magnetron sputtering, which uses direct current (DC) electrical power with very high frequency (VHF) or radio frequency (RF) electrical power superimposed thereupon as the sputtering electrical power, is more capable of forming an ITO film of low resistivity even at a relatively low temperature than DC type magnetron sputtering, in which only DC electrical power is used. The reason for this is that compared with DC type magnetron sputtering, the sputtering electrical power can be made lower in the case of DC/RF superimposition type magnetron sputtering, and hence damage to the ITO film by high-energy Ar (process gas) ions in the plasma is reduced. The mobility (the ease of movement of carriers such as electrons or positive holes through the substance), which determines the electrical conductivity of the ITO film, thus increases, and hence the resistivity of the ITO film is reduced (see, for example, Japanese Laid-open Patent Publication (Kokai) No. 10-265926). Moreover, in the case of DC/RF superimposition type magnetron sputtering, a method is also known in which the plasma is maintained in a stable state by maintaining the glow discharge in a stable state over time (see, for example, Japanese Laid-open Patent Publication (Kokai) No. 2000-034564).

FIG. 18 is a view useful in explaining a conventional DC/RF superimposition type magnetron sputtering apparatus.

As shown in FIG. 18, the conventional DC/RF superimposition type magnetron sputtering apparatus has a casing 202 inside which is formed a vacuum chamber 201, and an ITO cathode 203 that is attached to a side part of the casing 202 via an insulator (not shown). A large-area target 205 is attached to an inner surface of the ITO cathode 203 via a backing plate 204. A glass substrate (not shown) onto which the sputtering is to be carried out is disposed in the vacuum chamber 201 in facing relation to the target 205.

The ITO cathode 203 has a recessed part formed on a rear surface side thereof, and a magnet 206 for the sputtering is disposed in this recessed part. A side surface member that forms the recessed part of the ITO cathode 203 is generally composed of a stainless steel plate from the viewpoint of securing the strength of the ITO cathode 203, and the rear surface side thereof opens out. The ITO cathode 203 is covered by a cathode case 209 that supports a power supply unit 208.

The power supply unit 208 supported by the cathode case 209 has a circuit configuration (not shown) comprised of a radio frequency (RF) power source and a matching box that are connected in series with one another, and a direct current (DC) power source that is connected in parallel with the radio frequency (RF) power source and the matching box. The matching box has a circuit that is comprised primarily of a high-capacity capacitor.

The power supply unit 208 superimposes the DC electrical power and RF electrical power and supplies the resulting electrical power to the ITO cathode 203 as the sputtering electrical power. The RF electrical power output 210 from the matching box of the power supply unit 208 is connected to a point contact part 212 in approximately the center of an end surface of the side surface member of the ITO cathode 203 via a flexible metal band 211 made of copper or the like. The DC electrical power output 213 from the power supply unit 208 is connected in parallel to the RF electrical power, and is connected to a point contact part 215 in approximately the center of the end surface of the side surface member of the ITO cathode 203 via a coaxial cable 214. As a result, the sputtering electrical power supplied from the power supply unit 208 is propagated isotropically to the periphery of the target 205.

However, in the conventional DC/RF superimposition type magnetron sputtering apparatus shown in FIG. 18, the sputtering electrical power is supplied to the ITO cathode 203 via the point contact parts 212 and 215 between the flexible metal band 211 and coaxial cable 214 respectively and the ITO cathode 203, which are made of different types of metal to each other. The contact resistance is thus prone to changing, in which case the impedance of the ITO cathode 203 as a whole changes, and hence the glow discharge cannot be maintained in a stable state over time. As a result, an abnormal discharge or an ununiform plasma is prone to occur. With such a change in the impedance, the RF electrical power component influences the generation of the plasma more strongly than the DC electrical power component.

Moreover, the thickness of the ITO film on the substrate at a position corresponding to the power supply unit 208 supported by the cathode case 209 becomes less than the thickness of the ITO film at other positions on the substrate, and hence the thickness of the ITO film becomes ununiform. This is because, of the sputtering electrical power supplied to the ITO cathode 203, part of the radio frequency component leaks into the matching box via an opening in the cathode case 209 and hence power is no longer fed uniformly over the whole surface of the ITO cathode 203, or high frequency noise generated in the matching box interferes with the RF electrical power supplied to the ITO cathode 203, and hence the plasma density becomes small at the position corresponding to the point contact part 212.

It is a first object of the present invention to provide a sputtering apparatus that is capable of feeding a process gas uniformly over the whole surface of a target, while eliminating the effects of gas components discharged from an organic substance coated onto a surface of color filter substrates, and is thus capable of forming a coating of uniform thickness and quality over the whole surface of the substrates.

It is a second object of the present invention to provide a sputtering apparatus that is capable of forming a coating of uniform thickness and quality over the whole surface of substrates.

### DISCLOSURE OF THE INVENTION

To attain the first object of the present invention, a sputtering apparatus is provided that comprises: a vacuum chamber; at least one cathode disposed in the vacuum chamber and has attached thereto a plate-shaped target disposed in facing relation to at least one substrate that has an organic substance coated onto a surface thereof; and process gas supply means for feeding a process gas into the vicinity of the target; wherein the process gas supply means comprises a manifold that has a shape that is symmetrical about each of two mutually orthogonal central axes in the plane of the target and is disposed so as to surround the whole periphery of the target, and process gas discharge ports distributed over the whole of the manifold, for discharging the process gas onto the target.

According to the above constitution, the manifold has a shape that is symmetrical about each of two mutually orthogonal central axes in the plane of the target and is disposed so as to surround the whole periphery of the target, and moreover process gas discharge ports that discharge the process gas are provided in a manner being distributed over the whole of the manifold. As a result, when the target is sputtered, the process gas can be fed uniformly over the whole surface of the target from the process gas discharge ports, while eliminating the effects of gas components discharged from the organic substance coated onto the surface of the substrate(s), and hence a coating having uniform thickness and quality over the whole of the substrate(s) can be formed.

Preferably, the above manifold is divided into at least two manifold sections.

According to the above constitution, the manifold is divided into at least two manifold sections. As a result, each of the manifold sections can be made short, and thus reduction of the feed rate and pressure of the process gas caused by the manifold being too long can be prevented.

Also preferably, the above process gas supply means has at least two process gas supply sources, and each of the at least two manifold sections is connected to one of the process gas supply sources.

According to the above constitution, each of the manifold sections is connected to one of the process gas supply sources. As a result, the feed rate and pressure of the process gas can be controlled separately for each manifold section.

Also preferably, the process gas discharge ports comprise a plurality of holes or slits.

According to the above constitution, the process gas discharge ports comprise a plurality of holes or slits. As a result, the process gas discharge ports can easily be disposed distributed around the whole surface of the target.

Also preferably, the sputtering apparatus has plasma shield plates that are disposed so as to surround the whole periphery of the target and that shield the cathode and the manifold from the plasma during sputtering, wherein each of the plasma shield plates has a plurality of process gas passing holes provided in a manner being distributed over the whole of the plasma shield plate so as to adjust the flow of the process gas discharged from the process gas discharge ports towards the target.

According to the above constitution, a plurality of process gas passing holes provided in plasma shield plates that shield the cathode and the manifold from the plasma during sputtering adjust the flow of the process gas discharged from the process gas discharge ports towards the target. As a result, the process gas can be fed uniformly over the whole surface of the target while maintaining an effect of shielding the cathode and the manifold from the plasma during sputtering.

Also preferably, each of the process gas passing holes comprises a semicircular cut-out hole. According to the above constitution, each of the process gas passing holes comprises a semicircular cut-out hole. As a result, a sufficient flow adjustment effect can be obtained with simple processing.

To attain the second object of the present invention, a sputtering apparatus that forms an electrically conductive thin film on at least one substrate by a DC/RF superimposition type magnetron sputtering method is provided that comprises: a vacuum chamber; at least one cathode that is disposed in the vacuum chamber and has a target mounted thereon; movement means for moving the at least one substrate in the vacuum chamber in a predetermined direction while keeping the at least one substrate facing the target; and a plurality of power supply units that are connected to the at least one cathode and supply sputtering electrical power in which direct current electrical power and radio frequency electrical power are superimposed to the at least one cathode; wherein the plurality of power supply units are disposed to supply the sputtering electrical power to the at least one cathode at mutually different positions in a direction perpendicular to the above predetermined direction.

According to the above constitution, the plurality of power supply units are disposed so as to supply the sputtering electrical power to the at least one cathode at mutually different positions in a direction perpendicular to the predetermined direction. As a result, the density of the plasma formed in the vicinity of the target can be made uniform over the whole surface of the target, and hence a thin film of uniform thickness and quality can be formed over the whole of the substrate(s).

Preferably, the positions of the plurality of power supply units are determined such that the thickness distribution of the thin film on the at least one substrate based on the position of one of the power supply units complements the thickness distribution of the thin film on the at least one substrate based on the position of an adjacent one of the power supply units.

According to the above constitution, the positions of the plurality of power supply units are determined such that the thickness distribution of the thin film on the substrate(s) based on the position of one of the power supply units complements the thickness distribution of the thin film on the substrate(s) based on the position of an adjacent one of the power supply units. As a result, a thin film of yet more uniform thickness and quality can be formed over the whole of the substrate(s).

Also preferably, the power supply units are constituted so as to supply the sputtering electrical power to the at least one cathode via conductors in surface contact therewith along the direction perpendicular to the above predetermined direction.

According to the above constitution, the power supply units are disposed so as to supply the sputtering electrical power to the cathode(s) via conductors disposed in surface contact therewith along the direction perpendicular to the direction of movement of the substrate(s). As a result, the sputtering electrical power is propagated isotropically to the periphery of the target, and hence the density of the plasma formed in the vicinity of the target can be made spatially uniform reliably.

Also preferably, at least two of the cathodes are disposed along the above predetermined direction, wherein one of the power supply units is connected to one of the cathodes and another one of the power supply units is connected to another one of the cathodes.

According to the above constitution, at least two of the cathodes are disposed along the direction of movement of the substrate(s). As a result, the rate of formation of the thin film can be increased while maintaining the glow discharge in a stable state.

### BRIEF DESCRIPTION OF THE DRAWINGS

FIG. 1 is a partially cut-away plan view of main parts of a sputtering apparatus according to a first embodiment of the present invention;

FIG. 2 a horizontal sectional view showing part a in FIG. 1 in detail;

FIG. 3 is a view as viewed from a direction A in FIG. 2;

FIG. 4 is a view showing the appearance of a manifold 9 appearing in FIG. 3;

FIGS. 5A and 5B are views useful in explaining a plasma shield plate 11 appearing in FIG. 2; specifically:

FIG. 5A is a perspective view of the plasma shield plate 11;

FIG. 5B is a sectional view of the plasma shield plate 11 taken along line B-B in FIG. 5A;

FIGS. 6A and 6B are diagrams showing the effect of variation in process gas composition on visible light absorption coefficient and sputtering rate (thickness of film formed per unit time); specifically:

FIG. 6A shows the relationship between the amount of O₂ introduced and the visible light absorption coefficient;

FIG. 6B shows the relationship between the amount of O₂ introduced and the sputtering rate;

FIG. 7 is a schematic view showing ITO film property measurement points in Example and Comparative Examples 1 to 3;

FIG. 8 is a schematic view showing the arrangement of process as supply means and a target 8 in Comparative Example 1;

FIG. 9 is a schematic view showing the arrangement of process gas supply means and a target 8 in Comparative Example 3;

FIG. 10 is a schematic view showing the arrangement of process gas supply means and a target in a conventional sputtering apparatus;

FIG. 11 is a partially cut-away plan view of main parts of a sputtering apparatus according to a second embodiment of the present invention;

FIG. 12 is a diagram showing the constitution of the sputtering apparatus 100 appearing in FIG. 11;

FIG. 13 is a partially cut-away longitudinal sectional view of an ITO cathode 104a appearing in FIG. 11;

FIG. 14 is an end view of an opening of a recessed part of an ITO cathode 120 appearing in FIG. 13;

FIG. 15 is a partially cut-away transverse sectional view of the ITO cathode 104a appearing in FIG. 11;

FIG. 16 is a view useful in explaining cathode surfaces of the ITO cathodes 104a and 104b appearing in FIG. 11;

FIG. 17 is a schematic view showing ITO film property measurement points; and

FIG. 18 is a view useful in explaining a conventional DC/RF superimposition type magnetron sputtering apparatus.

### BEST MODE OF CARRYING OUT THE INVENTION

Embodiments of the present invention will now be described with reference to the diagrams.

(First Embodiment)

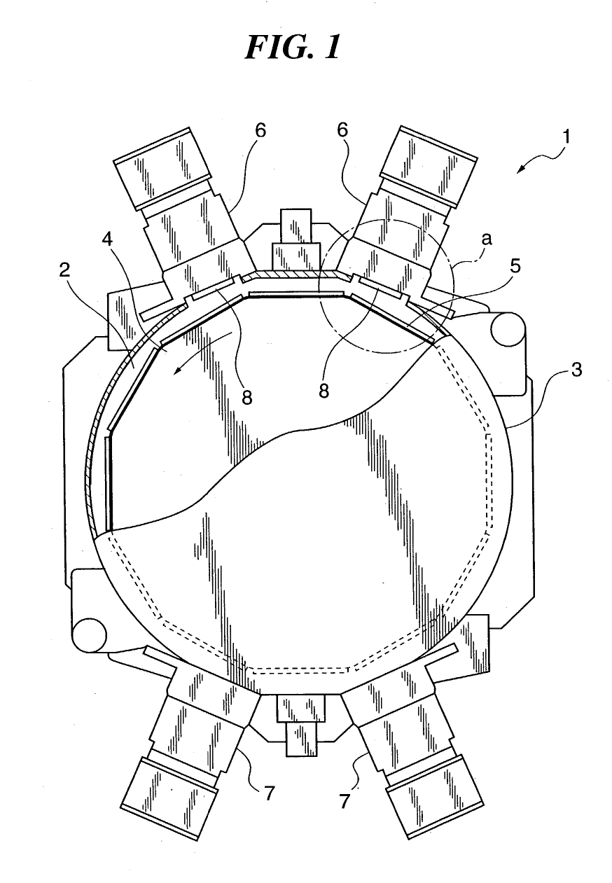

FIG. 1 is a partially cut-away plan view of main parts of a sputtering apparatus according to a first embodiment of the present invention.

In FIG. 1, the sputtering apparatus 1 is comprised of a casing 3 inside which is formed a vacuum chamber 2, a dodecagonal-prism-shaped carousel (substrate holder) 4 that is disposed in the center of the casing 3 for rotation by a motor (not shown) in the direction of the arrow in FIG. 1, a pair of ITO cathodes 6 that are disposed as sputtering cathodes in a peripheral side part of the casing 3, and a pair of SiO₂ cathodes 7 that are disposed opposite the ITO cathodes 6.

A plurality of substrates 5, for example four substrates 5, are arranged in a line in a vertical direction on each side surface of the carousel 4. Each substrate 5 is a rectangular color filter substrate of vertical dimension 300 to 500 mm and horizontal dimension 400 to 600 mm in which a color filter (organic substance) made of an organic resin is coated onto a surface of a glass substrate. By arranging a plurality of the substrates 5 in the vertical direction on each side surface of the carousel 4, the total area of the substrates 5 can be increased and hence the manufacturing efficiency can be improved. A rectangular target 8 of vertical dimension 800 to 1800 mm and horizontal dimension 100 to 200 mm is attached to a part of each ITO cathode 6 that faces into the vacuum chamber 2. Each target 8 is made of a sintered body, in which are mixed indium oxide and tin oxide in a predetermined ratio, for forming an ITO film (transparent electrically conductive film) on the substrates 5.

The sputtering apparatus 1 sputters the targets 8 with ions in a plasma using a magnetron sputtering method, and forms an ITO film from the targets 8 and an SiO₂ film on the substrates 5 mounted on the rotating carousel 4, thus manufacturing substrates having transparent electrically conductive films. Specifically, the sputtering apparatus 1 continuously rotates the carousel 4 at a predetermined rotational speed (2 to 4 revolutions per minute), and when each substrate 5 passes the front surface of the target 8 attached to each ITO cathode 6, raw material particles that come flying from the target 8 are deposited onto the substrate 5, thus forming an ITO film, until a predetermined film thickness is reached. An SiO₂ film is then similarly formed on the surface of the ITO film using the SiO₂ cathodes 7 until a predetermined film thickness is reached. It should be noted that the order of building up the ITO film and the SiO₂ film may be reversed.

In the present embodiment, a magnetron sputtering method is used to sputter the targets 8 and thus form an ITO film on each substrate 5 as described above. In the case that an ITO film is formed on substrates 5 in which an organic substance such as a color filter is coated onto a surface of a glass substrate, in general the substrate temperature must be made not more than 250° C. in the magnetron sputtering method. However, if an ITO film is formed using magnetron sputtering at such a temperature, then the resistivity may become 200 μΩ·cm or more, in which case the ITO film will have insufficient properties for use as an electrode in a color liquid crystal display apparatus.

In the magnetron sputtering, so that an ITO film having a low resistivity of not more than 200 μΩ·cm can be formed even at a low substrate temperature of the substrates 5 of not more than 250° C., a DC/RF superimposition type magnetron sputtering method in which electrical power in which radio frequency (RF) electrical power is superimposed on direct current (DC) electrical power is supplied to the ITO cathodes 6 is widely used.

However, in the DC/RF superimposition type magnetron sputtering method, the glow discharge generated by the DC/RF superimposition power source that supplies the electrical power in which RF electrical power is superimposed on DC electrical power has a characteristic that it is harder to maintain a stable discharge state compared with a glow discharge generated by a DC power source.

In the DC/RF superimposition type magnetron sputtering method, it is thus relatively difficult to make the plasma generated by the glow discharge from the DC/RF superimposition power source homogenous in space and time, and hence it is especially important to ensure the uniformity of the process gas, which intimately affects the state of the plasma. Moreover, the stability of the plasma and the stability of the glow discharge are integrally related to and affect one another, and hence if the plasma is maintained in a stable state, then the glow discharge will be maintained in a stable state. As a result, the occurrence of poor product quality caused by abnormal particles flying out from the surface of the target 8 due to an abnormal electrical discharge and attaching to the substrate 5 can be reduced.

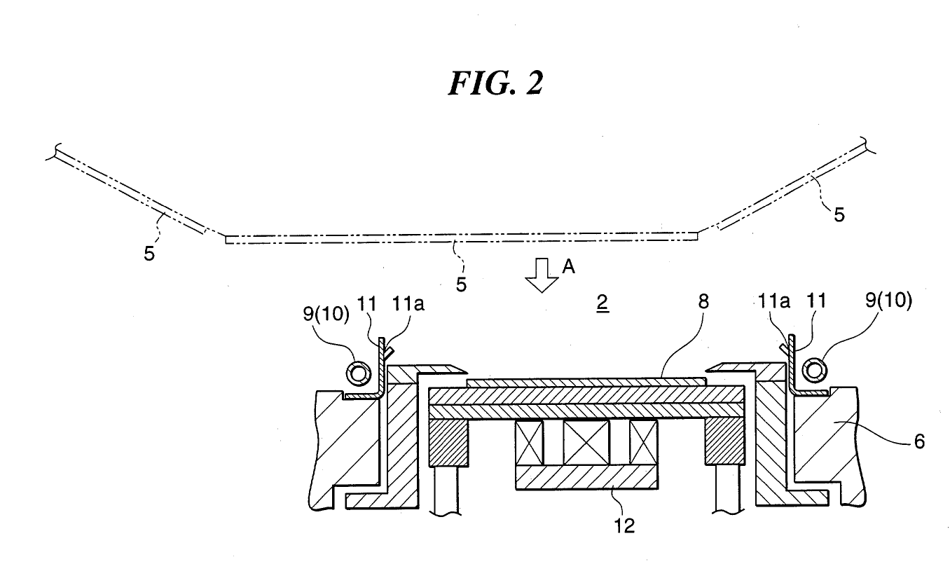

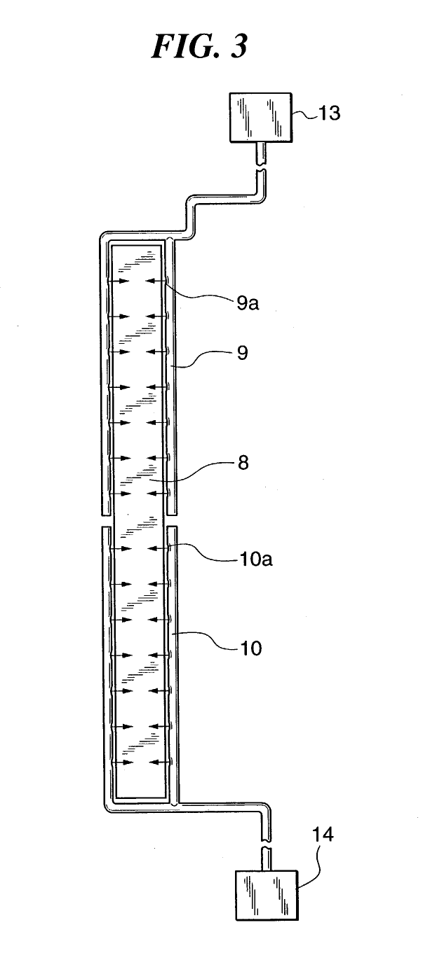

FIG. 2 is a horizontal sectional view showing part a in FIG. 1 in detail, and FIG. 3 is a view as viewed from a direction A in FIG. 2.

In FIG. 2, the target 8 is attached to a part of the ITO cathode 6 that faces into the vacuum chamber 2. On a rear surface side of the target 8 are disposed a DC/RF superimposition power source (not shown) that supplies the electrical power in which RF electrical power is superimposed on DC electrical power to the target 8, and magnetic field means 12 for carrying out sputtering of the target 8 efficiently. In the sputtering apparatus 1, sputtering is carried out on each substrate 5 when the substrate 5 passes a position facing the target 8 due to the rotation of the carousel 4.

Each substrate 5 has a surface thereof coated with a color filter made of an organic substance, and hence when the substrate 5 is heated or when a foundation film of silicon oxide or the like or a transparent electrically conductive film is formed on the surface of the substrate 5 by sputtering, a characteristic gas comprised of components adsorbed onto the surface of the substrate 5 and volatile components in the color filter is discharged. This characteristic gas can be represented by the general formula COₓ(0<x ≦2) and hence this gas will be hereinafter referred to as COₓ, and includes not only CO and CO₂ but also a gas having an unstable stoichiometric state. If this COₓ is discharged into the vacuum chamber 2, it may either act to consume an oxygen component in the process gas, or else may be reduced and may act to increase the oxygen component in the process gas. As a result, the properties of the plasma will fluctuate, and hence the uniformity of the thin film formed may be impaired. Moreover, if the thin film is of an oxide such as ITO, then fluctuations in the amount of the oxygen component in the process gas will affect the properties of the thin film directly.

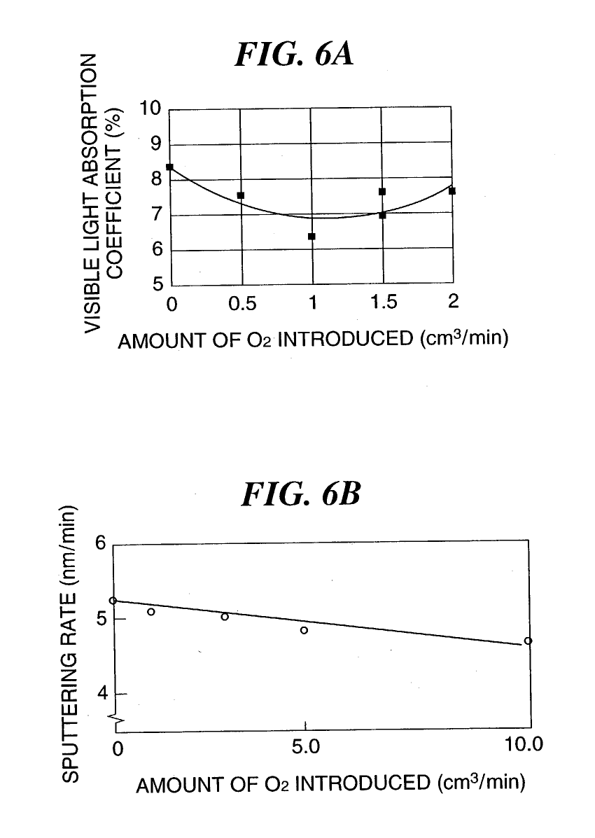

Results of experiments into effects caused by fluctuations in the amount of the oxygen component in the process gas when forming the ITO film on the substrate 5 are shown in FIGS. 6A and 6B. FIGS. 6A and 6B show results of measurements of the visible light absorption coefficient and the sputtering rate (thickness of film formed per unit time) when the amount of O₂ introduced in a process gas comprised of Ar and O₂ was varied with the amount of Ar introduced kept constant at 300 cm³/min (under standard conditions of 20° C. and 1 atmosphere). It can be seen that the visible light absorption coefficient and sputtering rate of the ITO film vary as the amount of O₂ introduced is varied.

In FIG. 2 and FIG. 3, a pair of manifolds (gas pipes) 9 and 10 for supplying the process gas onto the target 8 are disposed along the outer periphery of the target 8. The process gas is comprised of an inert gas such as Ar, although a reactive gas such as O₂ or N₂ may be added as necessary.

The manifolds 9 and 10 have a shape that is symmetrical about each of a mutually orthogonal horizontal central axis and vertical central axis in the plane of the target 8, and are disposed so as to surround the whole periphery of the target 8. Specifically, the manifold 9 is disposed so as to surround an upper half of the target 8, and the manifold 10 is disposed so as to surround a lower half of the target 8. Moreover, the manifolds 9 and 10 each have a plurality of process gas discharge ports 9a or 10a respectively for supplying the process gas uniformly over the whole surface of the target 8.

A process gas supply source 13 that supplies the process gas is connected to the manifold 9, and a process gas supply source 14 that supplies the process gas is connected to the manifold 10. The process gas supply source 13 controls the feed rate of the process gas to the manifold 9, and the process gas supply source 14 controls the feed rate of the process gas to the manifold 10. As a result, the feed rates of the process gas to the manifolds 9 and 10 can be controlled individually.

The process gas supplied to the manifold 9 and the process gas supplied to the manifold 10 have the same composition in the present embodiment. However, it is also possible to supply process gases having different compositions and/or at different pressures to the manifolds 9 and 10, respectively. As a result, the thickness and quality of the ITO film formed on the substrates 5 can be changed from place to place.

When supplying process gases having different compositions and/or at different pressures onto different parts of the target 8, in a sputtering process such as reactive sputtering in which a slight change in the state of introduction of the process gas has a large effect on the film formation properties, it is thought to be effective to monitor variations in the plasma concentration with a light emission state detector or the like, and partially incorporate a feedback system that changes the composition and/or pressure of the process gas for each part of the target 8 such that the variation in the light emission converges.

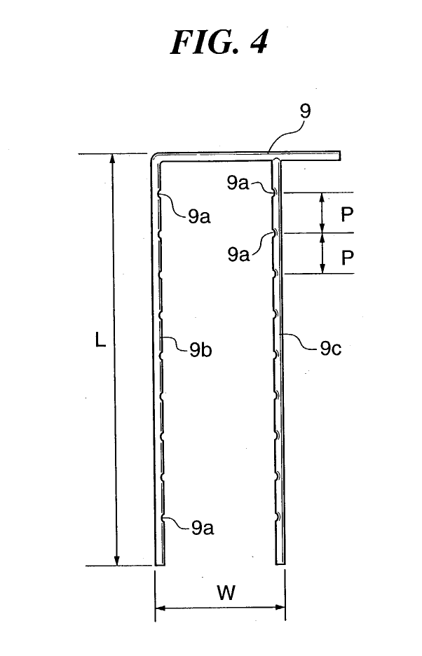

FIG. 4 is a view showing the outer appearance of the manifold 9 appearing in FIG. 3. The following explanation considers only the manifold 9, but the manifold 10 has a similar constitution.

In FIG. 4, the manifold 9 has two process gas blow-out pipes 9b and 9c, and each of the process gas blow-out pipes 9b and 9c has provided therein process gas discharge ports 9a distributed at equal intervals along the whole of the longitudinal direction thereof.

The spacing (pitch) between adjacent process gas discharge ports 9a is preferably not more than 50 mm. There are no particular limitations on the size and shape of the process gas discharge ports 9a; this size and shape should be set as appropriate so that the feed rate of the process gas onto the target 8 is approximately the same for all of the process gas discharge ports 9a, considering the pressure loss that occurs in the longitudinal direction of each of the process gas blow-out pipes 9b and 9c.

The length L of each of the process gas blow-out pipes 9b and 9c is preferably 800 mm. The length L is set with 1000 mm as an upper limit, this being to suppress variation in process gas feed rate and pressure due to differences in the distance from the process gas supply source 13 to each of the process gas discharge ports 9a. The distance W between the process gas blow-out pipes 9b and 9c is preferably 100 to 200 mm, in accordance with the size of the target 8.

The distance between the process gas discharge port 9a closest to the process gas supply source 13 and the process gas discharge port 9a furthest from the process gas supply source 13 is preferably not more than 1000 mm. In the case of feeding the process gas onto a target 8 having a relatively small area, the distance between the process gas discharge port 9a closest to the process gas supply source 13 and the process gas discharge port 9a furthest from the process gas supply source 13 will be reduced, in which case it may be possible to integrate the manifold 9 and manifold 10 into a single manifold.

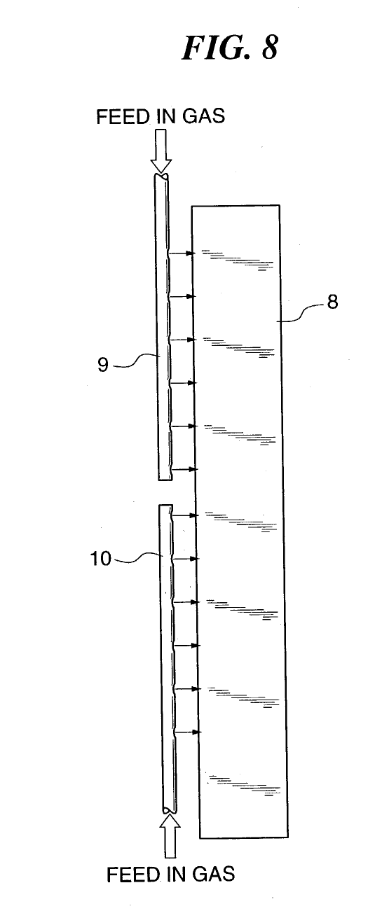

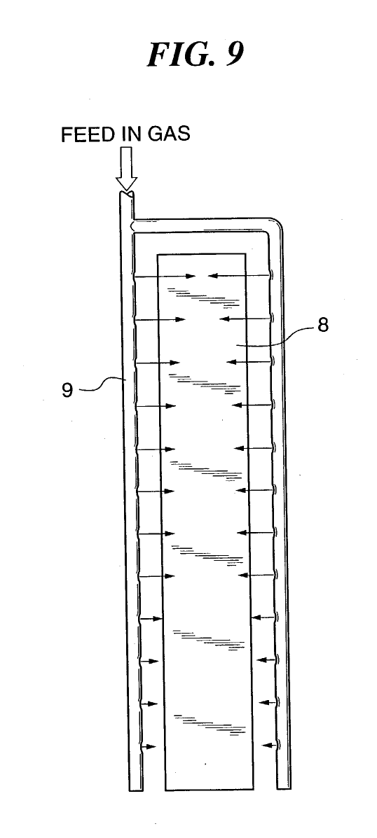

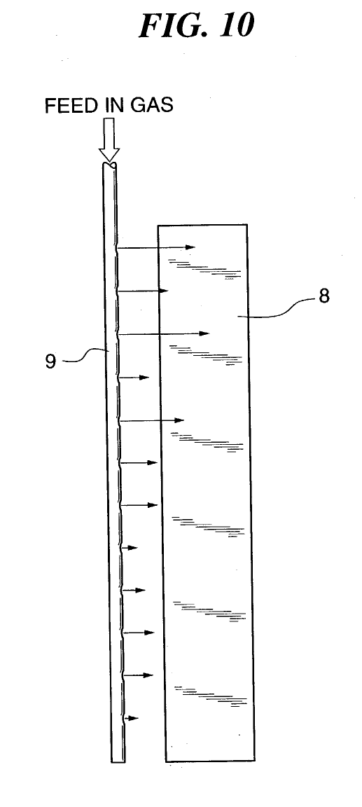

If the manifolds 9 and 10 are not arranged in a symmetrical shape about each of the mutually orthogonal horizontal central axis and vertical central axis in the plane of the target 8, or the distance between the process gas discharge port 9a closest to the process gas supply source 13 and the process gas discharge port 9a furthest from the process gas supply source 13 exceeds 1000 mm, or the manifolds 9 and 10 are not arranged so as to surround the whole periphery of the target 8 (FIGS. 8 to 10), then it will be difficult to feed the process gas uniformly over the whole surface of the target 8.

By dividing the manifold that feeds the process gas onto each target 8 into a manifold 9 and a manifold 10 as shown in FIG. 4, the lengths of the process gas blow-out pipes 9b and 9c (10b and 10c) in the manifolds 9 and 10 can be reduced, and hence differences in the process gas feed rate and pressure caused by differences in the positions of the process gas discharge ports 9a (10a) can be reduced.

According to the present embodiment, the manifold that feeds the process gas onto each target 8 is divided into two, i.e. into the manifold 9 and the manifold 10, and the manifolds 9 and 10 are connected to the process gas supply sources 13 and 14 respectively. As a result, the length L of the process gas blow-out pipes 9b and 9c (10b and 10c) can be reduced even if the target 8 has a large area, and hence the feed rate and pressure of the process gas can be made to be uniform throughout each of the process gas blow-out pipes 9b and 9c (10b and 10c).

In FIG. 2, plasma shield plates 11 are disposed along the outer periphery of the target 8 between the target 8 and the manifolds 9 and 10. Each plasma shield plate 11 has an L-shaped cross section, and forms a cathode for shielding members other than the target 8, i.e. the main body of the ITO cathode 6 and the manifolds 9 and 10, from the plasma during sputtering.

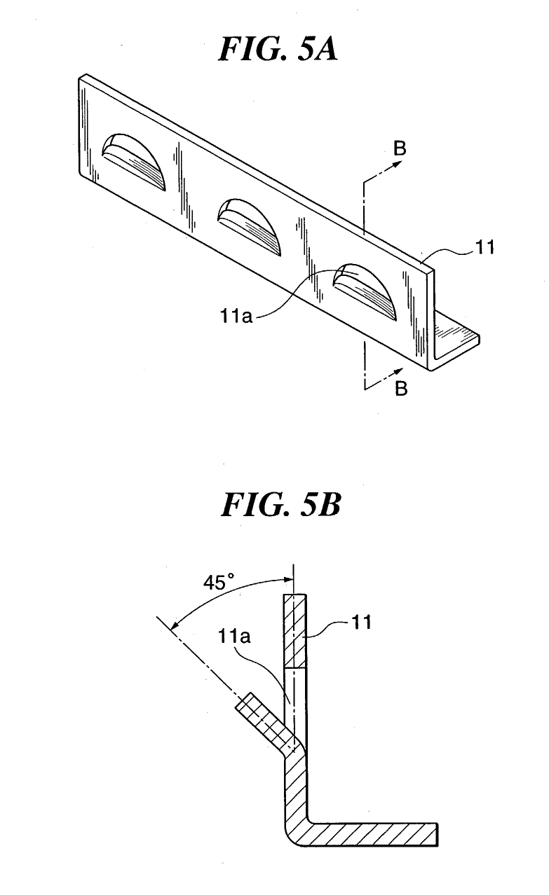

To feed the process gas discharged from the manifolds 9 and 10 uniformly onto the target 8, each plasma shield plate 11 is provided with a plurality of process gas passing holes 11a distributed along the whole of the longitudinal direction of the plasma shield plate 11. These process gas passing holes 11a are positioned facing the process gas discharge ports 9a and 10a of the manifolds 9 and 10. As shown in FIG. 5, described below, each process gas passing hole 11a is a semicircular cut-out hole.

FIGS. 5A and 5B are views useful in explaining the plasma shield plates 11 appearing in FIG. 2; specifically FIG. 5A is a perspective view of one of the plasma shield plates 11, and FIG. 5B is a sectional view of one of the plasma shield plates 11 taken along line B-B appearing-in FIG. 5A.

In FIG. 5A, each process gas passing hole 11a is formed by bending a semicircular cut-out part at an angle of about 45° towards the target 8 side. When the process gas passes through such a process gas passing hole 11a, the direction of flow of the process gas is partially changed by the bent part. As a result, the process gas discharged from the manifolds 9 and 10 is agitated and the flow of the process gas is adjusted, and the process gas can be made to arrive at the surface of the target 8 at a more uniform feed rate and pressure.

If the process gas passing holes 11a were each formed as a simple hole, then the flow rate of the process gas, which is discharged from a position separated from the target 8, would vary according to the position of the process gas discharge port 9a (or 10a), and hence it would be difficult to make the process gas arrive at the surface of the target 8 at a uniform feed rate and pressure.

According to the embodiment described above, manifolds 9 and 10 having a shape symmetrical about each of two mutually orthogonal central axes in the plane of the target 8 are disposed so as to surround the whole periphery of the target 8, and process gas discharge ports 9a and 10a distributed over the whole of the manifolds 9 and 10, for discharging the process gas onto the target 8. As a result, the process gas can be fed uniformly over the whole surface of the target 8, while eliminating the effects of gas components discharged from an organic substance coated onto the surface of the substrates 5, and hence a coating of uniform thickness and quality can be formed over the whole of the substrates 5.

### (EXAMPLE)

A specific example of the present embodiment will now be described.

The present inventors prepared test pieces by forming an ITO film on substrates 5 using the sputtering apparatus 1 according to the above described embodiment. Moreover, the present inventors also prepared similar test pieces using sputtering apparatuses in which the arrangement of the manifolds 9 and 10 and the target 8 was different to that in the sputtering apparatus 1. The distributions of the thickness and quality (surface resistance) of the ITO film formed on the test pieces, i.e. the ITO film properties, were then measured.

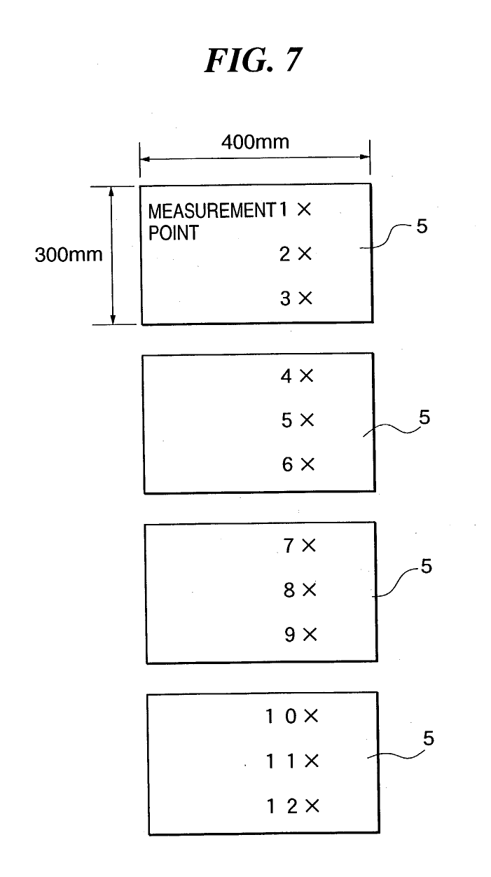

Specifically, four substrates 5 of vertical dimension 300 mm and horizontal dimension 400 mm were mounted on the carousel 4 in the sputtering apparatus 1 in parallel with the longitudinal direction of the targets 8 (the vertical direction), and an ITO film was formed on each substrate 5, thus preparing test pieces. As shown in FIG. 7, the ITO film properties of the test pieces were measured at 3 measurement points on each test piece, i.e. 12 measurement points in total, parallel to the longitudinal direction of the targets 8.

In the present Example, two sets of process gas supply means, namely the manifold 9 plus the process gas supply source 13, and the manifold 10 plus the process gas supply source 14, were disposed for each target 8, as shown in FIG. 3. The diameter of the manifolds 9 and 10 was 5 mm, the diameter of the process gas discharge ports 9a and 10a was 1.5 mm, the pitch of the process gas discharge ports 9a and 10a was 40 mm (equal spacings), and the distance between the process gas discharge port 9a or 10a closest to the process gas supply source 13 or 14 and the process gas discharge port 9a or 10a furthest from the process gas supply source 13 or 14 was 800 mm. Moreover, the diameter of the semicircular process gas passing holes 11a provided in the plasma shield plates 11 was 10 mm, and the angle through which part of the process gas was diverted by the semicircular process gas passing holes 11a was about 45°.

The process gas supply conditions and sputtering conditions when manufacturing the test pieces were the same for the Example and the Comparative Examples, and were as follows.

[Process Gas Supply Conditions and Sputtering Conditions]

1. Objective film thickness: 180 nm, objective resistance: 10Ω

2. Size of targets: width 127 mm, length 1625 mm

3. Process gas: Ar 600 cm³/min (300 cm³/min×2 lines) O₂ 2 cm³/min (1 cm³/min×2 lines)

4. Film deposition chamber pressure: 0.29 Pa (2.2×10⁻³ Torr)

5. Substrate temperature: 200° C.

6. Sputtering method: DC/RF superimposition power source (DC 1.5 kW, RF 3.0 kW)

7. Film formation time: About 25 minutes

8. Substrates: Vertical 300 mm×horizontal 400 m×thickness 0.7 mm (with color filter and resin protective film)

The measurement results of the ITO film properties of the test pieces manufactured under the above process gas supply conditions and sputtering conditions using the sputtering apparatus 1 are shown in Table 1. In Table 1, the ITO film thickness (nm), surface resistance (Ω) and resistivity (μm·cm) were measured at measurement points 1 to 12 on the substrates 5 shown in FIG. 7, and the maximum value, minimum value, mean value and distribution (variation) of each of these was calculated. The value of the distribution in Table 1 is expressed as “± (maximum value−minimum value)/(2×mean value)×100%”.

TABLE 1

| | ITO Film | Surface | |
|---|---|---|---|
| Measurement | Thickness | Resistance | Resistivity |
| Point | (nm) | (Ω) | (μ Ω · cm) |
| 1 | 181 | 9.9 | 179 |
| 2 | 182 | 9.7 | 177 |
| 3 | 182 | 9.9 | 180 |
| 4 | 180 | 10.3 | 185 |
| 5 | 178 | 10.0 | 178 |
| 6 | 176 | 10.4 | 184 |
| 7 | 172 | 10.6 | 182 |
| 8 | 177 | 10.2 | 180 |
| 9 | 178 | 10.3 | 183 |
| 10 | 178 | 10.1 | 179 |
| 11 | 178 | 10.1 | 179 |
| 12 | 174 | 10.7 | 186 |
| Maximum Value | 182 | 10.7 | 186 |
| Minimum Value | 172 | 9.7 | 177 |
| Mean Value | 178 | 10.2 | 181 |
| Distribution (%) | ±2.8 | ±4.9 | ±2.5 |

As shown in Table 1, the distribution of the ITO film thickness was ±2.8%, and the distribution of the surface resistance was ±4.9%, and hence film thickness and quality properties within an acceptable range for use as a product were obtained. It can be seen that, in the present Example, even though sputtering was carried out using targets 8 having a large area, due to the process gas supply means of the present embodiment, it was possible to form a coating having a uniform thickness and quality over the whole of a large-area substrate surface comprised of a plurality of substrates 5.

### Comparative Example 1)

Test pieces were prepared under the same process gas supply conditions and sputtering conditions as in the Example described above, using process gas supply means in which manifolds 9 and 10 were arranged on only one side of each target 8 in the width direction thereof (left/right direction) as shown in FIG. 8 (Comparative Example 1).

In this Comparative Example 1, the manifolds 9 and 10 were thus arranged without having symmetry in the left/right direction of the target 8, and the process gas was fed onto the target 8 from one side only. The other conditions such as the method of measuring the ITO film properties were the same as in the Example described above. The measurement results are shown in Table 2.

TABLE 2

| | ITO Film | Surface | |
|---|---|---|---|
| Measurement | Thickness | Resistance | Resistivity |
| Point | (nm) | (Ω) | (μ Ω · cm) |
| 1 | 162 | 11.4 | 184 |
| 2 | 171 | 10.6 | 181 |
| 3 | 174 | 10.2 | 178 |
| 4 | 179 | 10.1 | 181 |
| 5 | 172 | 10.3 | 176 |
| 6 | 178 | 10.1 | 179 |
| 7 | 173 | 10.2 | 177 |
| 8 | 189 | 9.7 | 184 |
| 9 | 197 | 9.5 | 186 |
| 10 | 195 | 9.4 | 183 |
| 11 | 198 | 9.3 | 184 |
| 12 | 198 | 9.2 | 183 |
| Maximum Value | 198 | 11.4 | 186 |
| Minimum Value | 162 | 9.2 | 176 |
| Mean Value | 182 | 10.0 | 181 |
| Distribution (%) | ±9.9 | ±11.0 | ±2.8 |

As shown in Table 2, the distribution of the thickness of the ITO films formed on the substrates 5 was ±9.9%, and the distribution of the surface resistance was ±11.0%, and hence these distributions were larger than in the Example described above. It is thought that, in the present Comparative Example 1, it was not possible to feed the process gas as uniformly over the whole surface of each large-area target 8 as in the Example, and hence the plasma was not maintained in a constant state throughout the film formation.

### (Comparative Example 2)

The shape of the process gas passing holes 11a provided in the plasma shield plates 11 was changed from the Example and simple holes of diameter 10 mm were used instead. Other than this, test pieces were prepared under the same process gas supply conditions and sputtering conditions as in the Example described above. The method of measuring the ITO film properties was also the same as in the Example described above. The measurement results are shown in Table 3.

TABLE 3

| | ITO Film | Surface | |
|---|---|---|---|
| Measurement | Thickness | Resistance | Resistivity |
| Point | (nm) | (Ω) | (μ Ω · cm) |
| 1 | 179 | 9.8 | 176 |
| 2 | 184 | 9.7 | 179 |
| 3 | 184 | 10.2 | 188 |
| 4 | 181 | 10.2 | 184 |
| 5 | 179 | 10.5 | 188 |
| 6 | 179 | 10.7 | 191 |
| 7 | 178 | 10.9 | 193 |
| 8 | 179 | 11.2 | 200 |
| 9 | 181 | 11.1 | 201 |
| 10 | 177 | 11.0 | 194 |
| 11 | 184 | 11.2 | 205 |
| 12 | 193 | 10.9 | 210 |
| Maximum Value | 193 | 11.2 | 210 |
| Minimum Value | 177 | 9.7 | 176 |
| Mean Value | 182 | 10.6 | 192 |
| Distribution (%) | ±4.4 | ±7.1 | ±8.8 |

As shown in Table 3, the distribution of the thickness of the ITO films formed on the substrates 5 was ±4.4% and the distribution of the surface resistance was ±7.1% and hence these distributions were somewhat larger than in the Example described above, although somewhat smaller than in Comparative Example 1. These results show that the process gas passing holes 11a having the shape exemplified in the embodiment described above have an effect of feeding the process gas uniformly over the whole surface of a large-area target 8.

### (Comparative Example 3)

Test pieces were prepared under the same process gas supply conditions and sputtering conditions as in the Example described above, using process gas supply means in which one set only of a manifold 9 and a process gas supply source 13 were disposed for each target 8.

In this Comparative Example 3, regarding the process gas discharge ports 9a provided in the manifold 9, the distance between the position of the process gas discharge port 9a closest to the process gas supply source 13 and the position of the process gas discharge port 9a furthest from the process gas supply source 13 was 1600 mm, i.e. about the same as the length of the target 8 in the longitudinal direction thereof (the vertical direction).

Even though there was only one process gas supply source 13, the total process gas feed rate was made to be the same as in the Example and Comparative Examples 1 and 2 described above, namely 600 cm³/min for the Ar and 2 cm³/min for the O₂. The other conditions such as the method of measuring the ITO film properties were the same as in the Example described above. The measurement results are shown in Table 4.

TABLE 4

| | ITO Film | Surface | |
|---|---|---|---|
| Measurement | Thickness | Resistance | Resistivity |
| Point | (nm) | (Ω) | (μ Ω · cm) |
| 1 | 165 | 10.1 | 167 |
| 2 | 175 | 10.2 | 178 |
| 3 | 176 | 10.0 | 176 |
| 4 | 180 | 10.0 | 181 |
| 5 | 181 | 9.7 | 176 |
| 6 | 179 | 10.2 | 183 |
| 7 | 182 | 9.8 | 179 |
| 8 | 192 | 9.5 | 183 |
| 9 | 193 | 9.5 | 183 |
| 10 | 189 | 9.6 | 182 |
| 11 | 186 | 9.4 | 175 |
| 12 | 191 | 9.9 | 190 |
| Maximum Value | 193 | 10.2 | 190 |
| Minimum Value | 165 | 9.4 | 167 |
| Mean Value | 182 | 9.8 | 179 |
| Distribution (%) | ±7.7 | ±4.1 | ±6.3 |

As shown in Table 4, the distribution of the thickness of the ITO films formed on the substrates 5 was ±7.7%, and the distribution of the surface resistance was ±4.1%, and the hence these distributions were somewhat larger than in the Example described above.

In the present Comparative Example 3, regarding the process gas discharge ports 9a provided in the manifold 9, the distance between the position of the process gas discharge support 9a closest to the process gas supply source 13 and the position of the process gas discharge port 9a furthest from the process gas supply source 13 was much greater than 1000 mm. It is thus thought that the feed rate and pressure of the process gas discharged from the process gas discharge ports 9a varied between the process gas discharge ports 9a, and hence that a uniform plasma was not generated over the whole surface of each target 8.

(Second Embodiment)

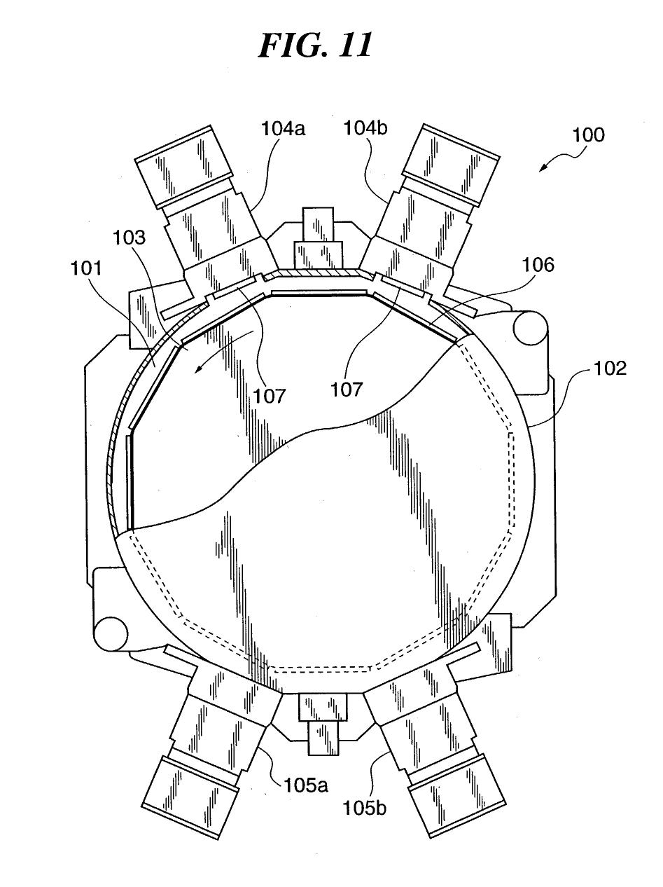

FIG. 11 is a partially cut-away plan view of main parts of a sputtering apparatus according to a second embodiment of the present invention.

In FIG. 11, the sputtering apparatus 100 is comprised of a casing 102 inside which is formed a vacuum chamber 101, a dodecagonal-prism-shaped carousel (substrate holder) 103 that is disposed in the center of the casing 102 for rotation by a motor (movement means) (not shown) in the direction of the arrow in FIG. 11, a pair of ITO cathodes 104a and 104b that are disposed as sputtering cathodes in a peripheral side part of the casing 102, and a pair of SiO₂ cathodes 105a and 105b that are disposed opposite the ITO cathodes 104a and 104b.

A plurality of substrates 106, for example four substrates 106, are arranged in a line in a vertical direction on each side surface of the carousel 103. Each substrate 106 is a rectangular color filter substrate of vertical dimension 300 to 500 mm and horizontal dimension 400 to 600 mm in which a color filter (organic substance) made of an organic resin is coated onto a surface of a glass substrate. By arranging a plurality of the substrates 106 in the vertical direction on each side surface of the carousel 103, the total area of the substrates 106 can be increased and hence the manufacturing efficiency can be improved. A large-area rectangular target 107 of vertical dimension 800 to 1800 mm and horizontal dimension 100 to 200 mm is attached to a part of each of the cathodes 104a and 104b that faces into the vacuum chamber 101. Each target 107 is made of a sintered body, in which are mixed indium oxide and tin oxide in a predetermined ratio, for forming an ITO film (electrically conductive thin film) on the substrates 106.

The sputtering apparatus 100 sputters the targets 107 with ions in a plasma using a magnetron sputtering method, and forms an ITO film from the targets 107 and an SiO₂ film on each of the substrates 106 mounted on the rotating carousel 103, thus manufacturing substrates having transparent electrically conductive films. Specifically, the sputtering apparatus 100 continuously rotates the carousel 103 at a predetermined rotational speed (2 to 4 revolutions per minute), and when each substrate 106 passes the front surface of the target 107 attached to the cathode 104a or 104b, raw material particles that come flying from the target 107 are deposited onto the substrate 106, thus forming an ITO film, until a predetermined film thickness is reached. An SiO₂ film is then similarly formed on the surface of the ITO film using the SiO₂ cathodes 105a and 105b until a predetermined film thickness is reached. It should be noted that the order of building up the ITO film and the SiO₂ film may be reversed.

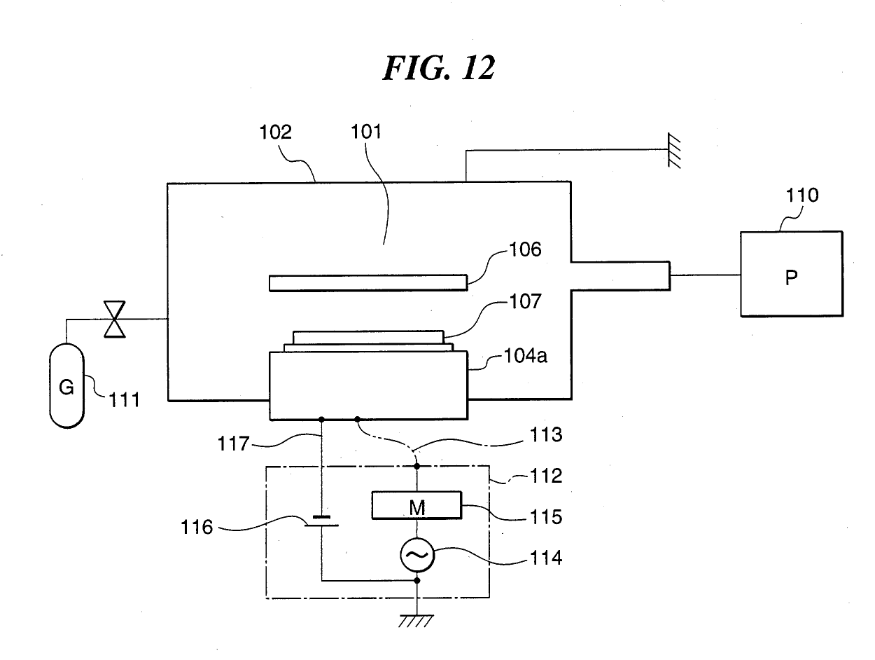

FIG. 12 is a diagram showing the constitution of the sputtering apparatus 100 appearing in FIG. 11. FIG. 12 shows, in schematic fashion, only those parts of the sputtering apparatus 100 necessary for the following explanation.

In the sputtering apparatus 100, the vacuum chamber 101 in the casing 102 is kept in a vacuum state by a vacuum pump 110, and at the same time a process gas is introduced into the vacuum chamber 101 from a sputtering gas cylinder 111, thus adjusting the sputtering atmosphere in the vacuum chamber 101. The process gas is comprised of an inert gas such as Ar, although a reactive gas such as O₂ or N₂ may be added as necessary.

Substrates 106 are disposed in a position facing the target 107 on the ITO cathode 104a. To generate a plasma for sputtering the target 107 in the vacuum chamber 101, a power supply unit 112 is connected to the ITO cathode 104a via a flexible metal band 113 and a coaxial cable 117.

The power supply unit 112 has a circuit configuration comprised of a radio frequency (RF) power source 114 and a matching box 115 that are connected in series with one another and are connected to the flexible metal band 113, and a direct current (DC) power source 116 that is connected in parallel with the radio frequency (RF) power source 114 and the matching box 115 and is connected to the coaxial cable 117. As a result of this circuit configuration, sputtering electrical power in which radio frequency (RF) electrical power supplied from the RF power source 114 via the matching box 115 and direct current (DC) electrical power supplied directly from the DC power source 116 are superimposed is supplied to the ITO cathode 104a (DC/RF superimposition method).

The matching box 115 has a circuit that is comprised primarily of a high-capacity capacitor for counteracting the effects of impedance fluctuations of the ITO cathode 104a. As a result, a drawback of electrical power supply using the DC/RF superimposition method that the RF electrical power component is affected by impedance fluctuations of the ITO cathode 104a can be prevented, and moreover the glow discharge can be stabilized and hence the occurrence of an abnormal discharge can be prevented. Generation of a large amount of foreign matter from the target 107 and members surrounding the target 107 can thus be prevented.

The RF electrical power is supplied to the ITO cathode 104a via the flexible metal band 113, and the DC electrical power is supplied to the ITO cathode 104a via the coaxial cable 117.

The sputtering electrical power in which the DC electrical power and RF electrical power obtained as described above are superimposed is supplied to the ITO cathode 104a in the vacuum chamber 101 in which the sputtering atmosphere has been adjusted, thus generating a plasma. The target 107 is sputtered by this plasma, thus forming an ITO film on the substrates 106.

A description will now be given of the method of connecting the flexible metal band 113 to the ITO cathode 104a.

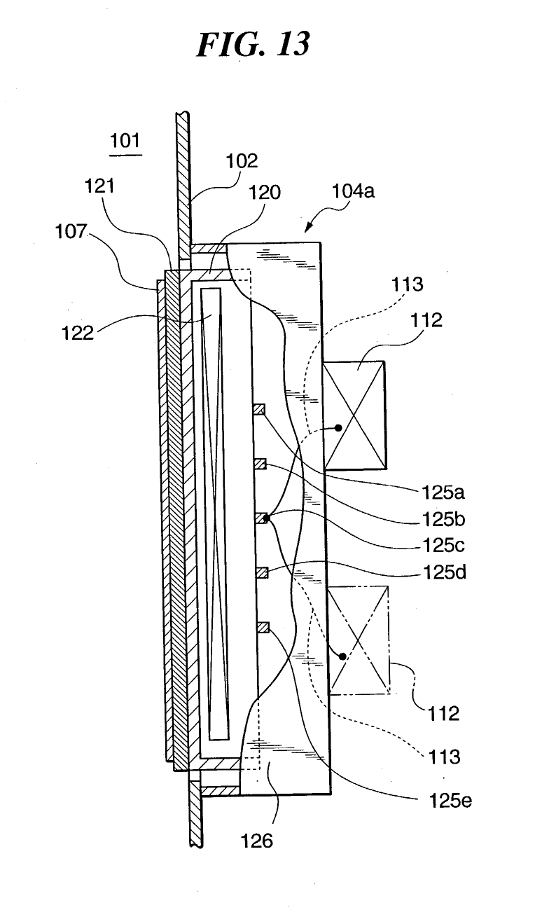

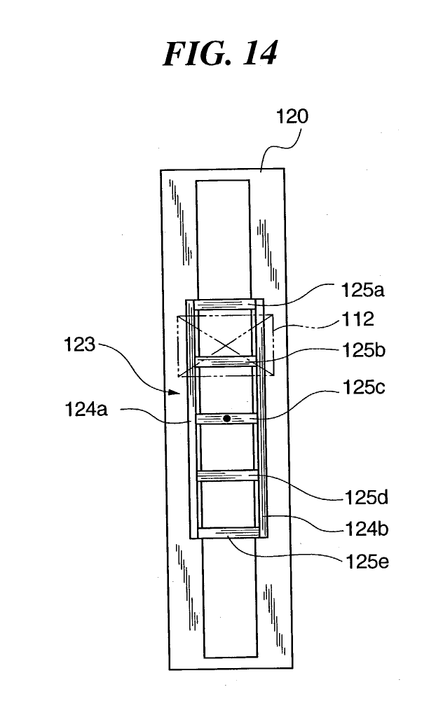

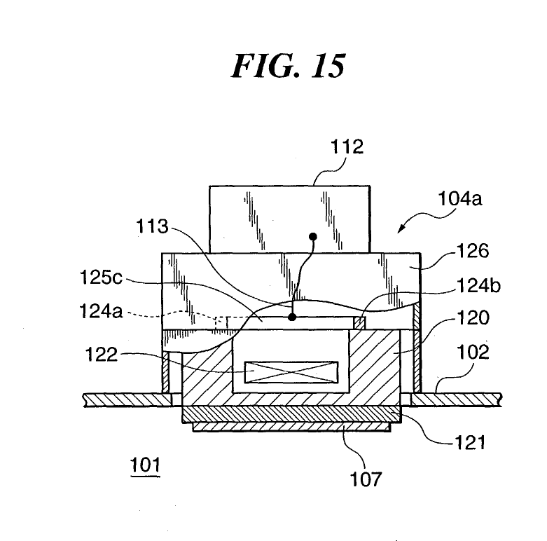

FIG. 13 is a partially cut-away longitudinal sectional view of the ITO cathode 104a appearing in FIG. 11, FIG. 14 is an end view of the opening of the recessed part of the ITO cathode 120 appearing in FIG. 13, and FIG. 15 is a partially cut-away transverse sectional view of the ITO cathode 104a appearing in FIG. 11. The following description will be given while referring to FIG. 11 and FIG. 12 as appropriate; the same constituent elements in FIG. 11 and FIG. 12 are designated by the same reference numerals. The following description focuses on the ITO cathode 104a, but it should be noted that the ITO cathodes 104a and 104b differ from one another only in the position of installation of the power supply unit 112 and the position of connection of the flexible metal band 113.

In the following description, it is not necessary to mention the supply of the DC electrical power, and hence parts relating to the DC electrical power are not shown in the drawings referred to.

As shown in FIGS. 13 to 15, the ITO cathode 104a has an ITO cathode 120 that is attached to a side part of the casing 102 inside which is formed the vacuum chamber 101. The target 107 is mounted on an inner surface of the ITO cathode 120 via a backing plate 121. The glass substrates (not shown) onto which the sputtering is to be carried out are disposed in the vacuum chamber 101 in facing relation to the target 107. The ITO cathode 120 has a recessed part formed on a rear surface side thereof, and a magnet 122 for the sputtering is disposed in this recessed part. An RF connection conductor 123, described below, is mounted in the opening of the recessed part of the ITO cathode 120. The recessed part of the ITO cathode 120 and the RF connection conductor 123 are covered by a cathode case 126 that supports the power supply unit 112.

The RF connection conductor 123 has a ladder shape, and is comprised of vertical conductors 124a and 124b (thickness 2 mm, width 40 mm, length 1066 mm) made of copper that are fixed to each side of the opening of the recessed part so as to be in surface contact with an end surface of the ITO cathode 120, and horizontal conductors 125a to 125e made of copper that are spaced at equal intervals and connect the vertical conductors 124a and 124b together. The vertical conductors 124a and 124b are in surface contact with the ITO cathode 120. along a direction perpendicular to the direction of movement of the substrates 106, i.e. along the longitudinal direction of the target 107.

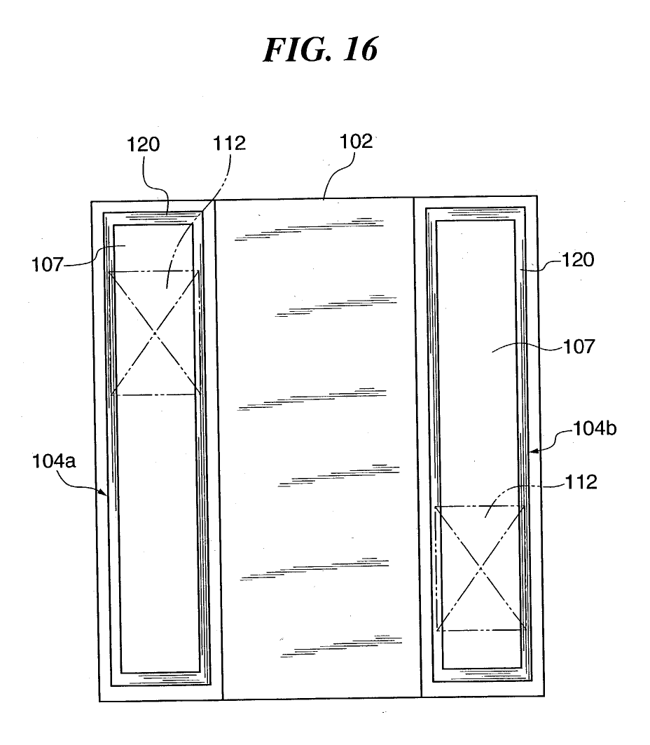

The power supply unit 112 is mounted on an upper part of the ITO cathode 104a (see FIG. 16), the flexible metal band 113 (thickness 0.2 mm, width 40 mm) is led out from an output of the power supply unit 112, and an end of the flexible metal band 113 is connected to a substantially central part of the horizontal conductor 125c by a bolt (not shown). In the case of the ITO cathode 104b, on the other hand, the power supply unit 112 is mounted on a lower part of the ITO cathode 104b (see FIG. 16), and as in the case of the ITO cathode 104a, the flexible metal band 113 is led out from an output of the power supply unit 112, and an end of the flexible metal band 113 is connected to a substantially central part of the horizontal conductor 125c by a bolt (not shown).

As described above, the two power supply units 112 that supply sputtering electrical power to the ITO cathodes 104a and 104b respectively can be mounted in mutually different positions in the direction perpendicular to the direction of movement of the substrates 106. It is preferable for the flexible metal band 113 led out from each power supply unit 112 to be connected to the center of the horizontal conductor 125c in a substantially central part of the RF connection conductor 123. The reason for this is that the RF electrical power thus supplied to the center of the RF connection conductor 123 can then be propagated isotropically to the periphery of the target 107 via the RF connection conductor 123 and the ITO cathode 120 in surface contact with the RF connection conductor 123.

According to the present embodiment, in the case of the ITO cathode 104a, the power supply unit 112 is mounted on the upper part of the ITO cathode 104a and is connected to the substantially central part of the horizontal conductor 125c via the flexible metal band 113, and in the case of the ITO cathode 104b, the power supply unit 112 is mounted on the lower part of the ITO cathode 104b and is connected to the substantially central part of the horizontal conductor 125c via the flexible metal band 113. The sputtering electrical power is thus supplied to the ITO cathodes 120 with the two power supply units 112 disposed in mutually different positions in the direction perpendicular to the direction of movement of the substrates 106. As a result, the ITO film thickness distribution on the substrates 106 based on one of the power supply unit positions complements the ITO film thickness distribution on the substrates 106 based on the other power supply unit position. The density of the plasma formed in the vicinity of the targets 107 can thus be made uniform across the whole of the targets 107, and hence an ITO film having uniform thickness and quality can be formed over the whole of the substrates 106.

In the embodiment described above, three or more ITO cathodes 104 may be provided. For example, in the case that the number of ITO cathodes 104 provided is three, a power supply unit 112 is mounted on each of the ITO cathodes 104 such that the installation positions of the power supply units 112 on the ITO cathodes 104 are placed at equal intervals in the vertical direction (the direction perpendicular to the direction of movement of the substrates 106).

Using a plurality of ITO cathodes 104 as in the embodiment described above is an apparatus form that has been adopted conventionally for the industrial reason that the film formation rate can be raised without applying a large sputtering electrical power to each of the targets 107, i.e. without risking making the electrical discharges unstable. The present invention utilizes this advantage, but also produces a large effect in that uniform ITO films can be formed on large-area substrates 106.

In the embodiment described above, one power supply unit 112 was disposed per ITO cathode 104, but a plurality of power supply units 112 may be disposed per ITO cathode 104. In this case, the installation positions of the power supply units 112 on the ITO cathode 104 are distributed at equal intervals in the vertical direction (the direction perpendicular to the direction of movement of the substrates 106).

Because the flexible metal band 113 is attached to the horizontal conductors 125a to 125e which are made of the same metal as the flexible metal band 113, namely copper, changes in the impedance of the ITO cathode 120 as a whole due to changes in the contact resistance can be prevented.

Moreover, the sputtering electrical power that is supplied via the horizontal conductors 125a to 125e supplied to the ITO cathode 120 from the vertical conductors 124a and 124b which are mounted in parallel with the longitudinal direction of the target 107, and hence the sputtering electrical power can be propagated isotropically around the target 107. Furthermore, the vertical conductors 124a and 124b and the ITO cathode 120 are in surface contact with one another, and hence the isotropic propagation of the sputtering electrical power can be carried out reliably.

Moreover, it is preferable for the RF connection conductor 123 on each of the ITO cathodes 104 to be disposed such that the periphery of the RF connection conductor 123 extends parallel to the periphery of the target 107 and moreover the long sides and short sides of the RF connection conductor 123 extend respectively in the same directions as the long sides and short sides of the target 107. As a result, the supplied sputtering electrical power can be propagated yet more isotropically around the target 107.

There are no particular limitations on the dimensions of the RF connection conductor 123 and the method of connection of the flexible metal band 113, provided the details thereof conform with the purport of the present invention. Moreover, in general various members such as cooling water pipes are mounted on the rear surface of each of the ITO cathodes 104a and 104b to which the sputtering electrical power is supplied, and the RF connection conductor 123 and the flexible metal band 113 should be disposed and connected so as not to interfere with these members.

The method of connection of the coaxial cable 117 that provides the DC electrical power may be the same as the method of connection of the flexible metal band 113.

Moreover, the material from which the flexible metal band 113 is made is generally copper, but may be selected from materials having good conductivity and suitable weather resistance; in addition to copper, examples include silver, aluminum and gold.

For the same reasons, the material from which the vertical conductors 124a and 124b and the horizontal conductors 125a to 125e are made may be selected from copper, silver, aluminum, gold and the like.

Furthermore, to obtain a uniform film thickness distribution over all of the substrates 106 mounted on each of the side surfaces of the carousel 103, the positions from which the process gas is fed from the sputtering gas cylinder 111 into the vacuum chamber 101 and the gas pressure distribution may be manipulated, the shape of the targets 107 may be devised, and/or film thickness correcting plates may be used.

Moreover, in the case that there is one power supply unit 112 per ITO cathode 104, the power supply unit 112 may be mounted at one end of the ITO cathode 104, and an earthing circuit at the other end of the ITO cathode 104 via a variable capacitor. As a result, an electrical power equal to the sputtering electrical power that returns to the power supply unit 112 side via the opening of the cathode case 126 on which the power supply unit 112 is mounted is earthed via the earthing circuit, and hence the distribution of the sputtering electrical power supplied to the ITO cathode 104 as a whole can be made uniform.

Furthermore, the embodiment described above targeted the ITO cathodes 104a and 104b, but the present invention can also be applied to the SiO₂ cathodes 105a and 105b.

### (EXAMPLE)

A specific example of the present embodiment will now be described.

Four substrates 106 were arranged in a line in the direction (the vertical direction) perpendicular to the direction of rotation of the carousel 103 in FIG. 11, and two power supply units 112 were mounted either side of the center of the cathode cases 126 as shown in FIG. 13. An ITO film was formed on the substrates 106 by supplying sputtering electrical power to the ITO cathodes 104, thus preparing test pieces.

[ITO Film Formation Conditions]

1. Objective film thickness: 180 nm, objective resistance: 10Ω

2. Size of targets: width 127 mm, length 1625 mm

3. Process gas: Ar 600 cm³/min (300 cm³/min×2 lines) O₂ 2 cm³/min (1 cm³/min×2 lines)

4. Vacuum chamber pressure: 0.29 Pa (2.2×10⁻³ Torr)

5. Substrate temperature: 200° C.

6. Sputtering method: DC/RF superimposition method (DC 1.5 kW, RF 3.0 kW)

7. Number of power supply units used: 2

8. Film formation time: About 25 minutes for Example

9. Substrates: 0.7 mm×300 mm×400m, with color filter and resin protective film

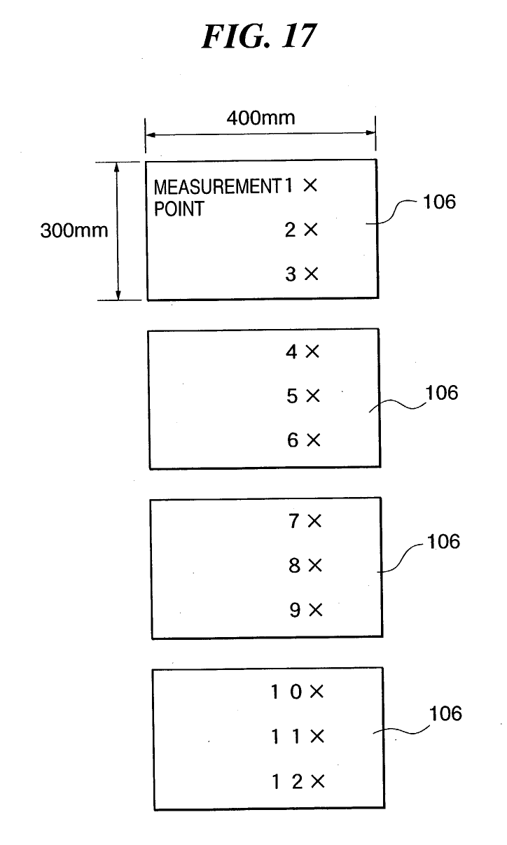

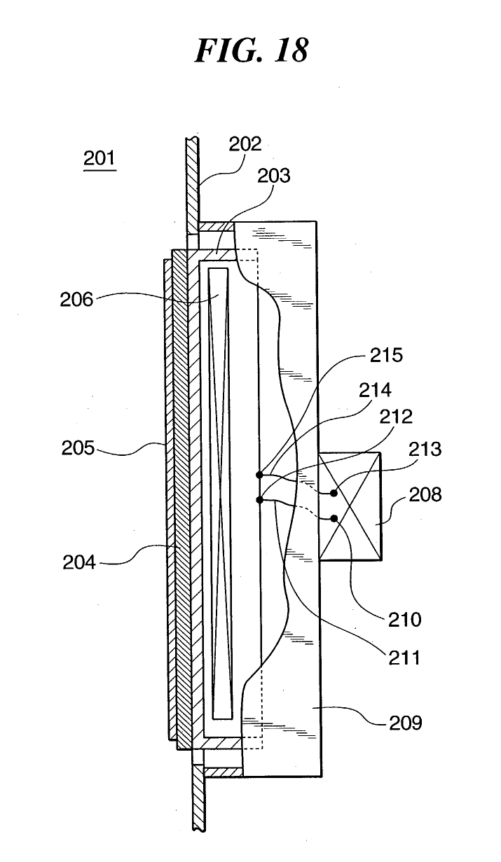

As shown in FIG. 17, four substrates 106 were mounted on the carousel 103 so as to be arranged in a line in the longitudinal direction of the targets 107 with the 300 mm sides of the substrates 106 being vertical. There were 3 ITO film property measurement points on each substrate 106 in the direction corresponding to the longitudinal direction of the targets 107, and these measurement points were numbered 1 to 12 from the top downwards. Three property values were measured at each measurement point, namely the ITO film thickness (nm), the surface resistance (Ω) and the resistivity (μΩ·cm). The distribution (variation) of each of the measured property values is expressed as “±(maximum value−minimum value)/(2×mean value)×100%”.

Moreover, as Comparative Examples, test pieces were prepared by forming an ITO film on substrates 106 by supplying sputtering electrical power to the ITO cathode 104a or 104b for about 50 minutes from only one of the two power supply units 112 appearing in FIG. 13 (Comparative Examples 1 and 2).

Results for Comparative Example 1 obtained when the sputtering electrical power was supplied to the ITO cathode 104 from only the upper power supply unit 112 are shown in Table 5.

TABLE 5

| | ITO Film | Surface | |
|---|---|---|---|
| Measurement | Thickness | Resistance | Resistivity |
| Point | (nm) | (Ω) | (μ Ω · cm) |
| 1 | 176 | 10.40 | 183 |
| 2 | 180 | 10.30 | 186 |
| 3 | 182 | 10.20 | 186 |
| 4 | 180 | 9.94 | 179 |
| 5 | 182 | 10.30 | 187 |
| 6 | 186 | 10.10 | 187 |
| 7 | 193 | 9.84 | 190 |
| 8 | 198 | 9.35 | 185 |
| 9 | 198 | 9.00 | 178 |
| 10 | 196 | 9.31 | 182 |
| 11 | 203 | 8.80 | 179 |
| 12 | 203 | 8.70 | 177 |
| Maximum Value | 203 | 10.40 | 190 |
| Minimum Value | 176 | 8.70 | 177 |
| Mean Value | 190 | 9.68 | 183 |
| Distribution (%) | ±7.1 | ±8.8 | ±3.6 |

As can be seen from Table 5, in Comparative Example 1 the ITO film thickness was smaller the lower the number of the measurement point, and the distribution of the ITO film thickness was large at ±7.1%. Moreover, the surface resistance was larger the lower the number of the measurement point, and the distribution of the surface resistance was large at ±8.8%. However, the position of the power supply unit 112 did not have a large effect on the resistivity, and the distribution of the resistivity was only ±3.6%; it was thus found that the surface resistance depends on only the film thickness.

Results for Comparative Example 2 obtained when the sputtering electrical power was supplied to the ITO cathode 104 from only the lower power supply unit 112 are shown in Table 6.

TABLE 6

| | ITO Film | Surface | |
|---|---|---|---|
| Measurement | Thickness | Resistance | Resistivity |
| Point | (nm) | (Ω) | (μ Ω · cm) |
| 1 | 199 | 9.21 | 183 |
| 2 | 199 | 9.35 | 186 |
| 3 | 196 | 9.36 | 183 |
| 4 | 198 | 9.45 | 187 |
| 5 | 190 | 9.72 | 185 |
| 6 | 175 | 10.20 | 178 |
| 7 | 179 | 10.00 | 179 |
| 8 | 173 | 10.20 | 177 |
| 9 | 180 | 10.10 | 182 |
| 10 | 175 | 10.20 | 179 |
| 11 | 172 | 10.60 | 183 |
| 12 | 163 | 11.30 | 185 |
| Maximum Value | 199 | 11.30 | 187 |
| Minimum Value | 163 | 9.21 | 177 |
| Mean Value | 184 | 9.97 | 182 |
| Distribution (%) | ±9.8 | ±10.5 | ±2.7 |

As can be seen from Table 6, in Comparative Example 2 the ITO film thickness was smaller the higher the number of the measurement point, and the distribution of the ITO film thickness was large at ±9.8%. Moreover, the surface resistance was larger the higher the number of the measurement point, and the distribution of the surface resistance was large at ±10.5%. However, as in Comparative Example 1, the position of the power supply unit 112 did not have a large effect on the resistivity, and the distribution of the resistivity was only ±2.7%.

In contrast to the above, results obtained when the sputtering electrical power was supplied to the ITO cathodes 104 using the film formation conditions of the Example are shown in Table 7.

TABLE 7

| | ITO Film | Surface | |
|---|---|---|---|
| Measurement | Thickness | Resistance | Resistivity |
| Point | (nm) | (Ω) | (μ Ω · cm) |
| 1 | 185 | 9.99 | 185 |
| 2 | 191 | 9.99 | 190 |
| 3 | 187 | 9.81 | 184 |
| 4 | 185 | 9.76 | 180 |
| 5 | 186 | 9.99 | 186 |
| 6 | 186 | 10.30 | 192 |
| 7 | 178 | 10.40 | 185 |
| 8 | 182 | 10.00 | 182 |
| 9 | 186 | 9.99 | 186 |
| 10 | 178 | 10.00 | 178 |
| 11 | 185 | 10.00 | 185 |
| 12 | 180 | 10.60 | 191 |
| Maximum Value | 191 | 10.60 | 192 |
| Minimum Value | 178 | 9.76 | 178 |
| Mean Value | 184 | 10.07 | 185 |
| Distribution (%) | ±3.5 | ±4.2 | ±3.8 |

As can be seen from Table 7, in the Example the various property values, namely the ITO film thickness, the surface resistance and the resistivity, were not affected by the position of the measurement point; the distributions thereof were ±3.5%, ±4.2% and ±3.8% respectively. The distributions of the property values were thus within acceptable ranges for use as a product, and it was possible to make the thickness and quality of the ITO film formed on the substrates 106 mounted on the carousel 103 uniform over all of the substrates 106.

### Industrial Applicability

As described in detail above, according to the sputtering apparatus of the present invention, the manifold has a shape that is symmetrical about each of two mutually orthogonal central axes in the plane of the target and is disposed so as to surround the whole periphery of the target, and moreover process gas discharge ports that discharge a process gas are provided in a manner being distributed over the whole of the manifold. As a result, when the target is sputtered, the process gas can be fed uniformly over the whole surface of the target from the process gas discharge ports, while eliminating the effects of gas components discharged from the organic substance coated onto the surface of the substrate(s), and hence a coating having uniform thickness and quality over the whole of the substrate(s) can be formed.

Moreover, preferably, the manifold is divided into at least two manifold sections. As a result, each of the manifold sections can be made short, and thus reduction of the feed rate and pressure of the process gas caused by the manifold being too long can be prevented.

Moreover, preferably, the process gas supply means has at least two process gas supply sources, and each of the at least two manifold sections is connected to one of the process gas supply sources. As a result, the feed rate and pressure of the process gas can be controlled separately for each manifold section.

Moreover, preferably, the process gas discharge ports comprise a plurality of holes or slits. As a result, the process gas discharge ports can easily be disposed distributed around the whole surface of the target.

Moreover, preferably, a plurality of process gas passing holes provided in plasma shield plates that shield the cathode and the manifold from the plasma during sputtering adjust the flow of the process gas discharged from the process gas discharge ports towards the target. As a result, the process gas can be fed uniformly over the whole surface of the target while maintaining an effect of shielding the cathode and the manifold from the plasma during sputtering.

Moreover, preferably, each of the process gas passing holes comprises a semicircular cut-out hole. As a result, a sufficient flow adjustment effect can be obtained with simple processing.

Furthermore, according to the sputtering apparatus of the present invention, a plurality of power supply units that supply the sputtering electrical power to the cathode(s) are mounted in mutually different positions in a direction perpendicular to the direction of movement of the substrate(s). As a result, the density of the plasma formed in the vicinity of the target can be made uniform over the whole surface of the target, and hence a thin film of uniform thickness and quality can be formed over the whole of the substrate(s).

Moreover, preferably, the positions of the plurality of power supply units are determined such that the thickness distribution of the thin film on the substrate(s) based on the position of one of the power supply units complements the thickness distribution of the thin film on the substrate(s) based on the position of an adjacent one of the power supply units. As a result, a thin film of yet more uniform thickness and quality can be formed over the whole of the substrate(s).

Moreover, preferably, the power supply units are constituted so as to supply the sputtering electrical power to the cathode(s) via conductors disposed in surface contact therewith along the direction perpendicular to the direction of movement of the substrate(s). As a result, the sputtering electrical power is propagated isotropically to the periphery of the target, and hence the density of the plasma formed in the vicinity of the target can be made spatially uniform reliably.

Moreover, preferably, a plurality of the cathodes are disposed along the direction of movement of the substrates. As a result, the rate of formation of the thin film can be increased while maintaining the glow discharge in a stable state.

What is claimed is:

1. A sputtering apparatus comprising:
a vacuum chamber;
at least one cathode disposed in said vacuum chamber and having attached thereto a plate-shaped target disposed in facing relation to at least one substrate that has an organic substance coated onto a surface thereof; and
process gas supply means for feeding a process gas into a vicinity of said target;
wherein said process gas supply means comprises a manifold that has a shape that is symmetrical about each of two mutually orthogonal central axes in a plane of said target and is disposed so as to surround a whole periphery of said target, and process gas discharge ports distributed over a whole of said manifold, for discharging the process gas onto said target.

2. A sputtering apparatus as claimed in claim 1, wherein said manifold is divided into at least two manifold sections.

3. A sputtering apparatus as claimed in claim 2, wherein said process gas supply means has at least two process gas supply sources, and each of said at least two manifold sections is connected to one of said process gas supply sources.

4. A sputtering apparatus as claimed in any one of claims 1 through 3, wherein said process gas discharge ports comprise a plurality of holes or slits.

5. A sputtering apparatus as claimed in any one of claims 1 through 4, further comprising plasma shield plates disposed so as to surround a whole periphery of said target, for shielding said cathode and said manifold from a plasma during sputtering, and wherein each of said plasma shield plates has a plurality of process gas passing holes distributed over a whole of said plasma shield plate, for adjusting flow of the process gas discharged from said process gas discharge ports towards said target.

6. A sputtering apparatus as claimed in claim 5, wherein each of said process gas passing holes comprises a semicircular cut-out hole.

7. A sputtering apparatus that forms an electrically conductive thin film on at least one substrate by a DC/RF superimposition type magnetron sputtering method, the sputtering apparatus comprising:
a vacuum chamber;
at least one cathode disposed in said vacuum chamber and having a target mounted thereon;
movement means for moving the at least one substrate in said vacuum chamber in a predetermined direction while keeping the at least one substrate facing said target; and
a plurality of power supply units connected to said at least one cathode, for supplying sputtering electrical power in which direct current electrical power and radio frequency electrical power are superimposed to said at least one cathode;
wherein said plurality of power supply units are disposed so as to supply the sputtering electrical power to said at least one cathode at mutually different positions in a direction perpendicular to the predetermined direction.

8. A sputtering apparatus as claimed in claim 7, wherein positions of said plurality of power supply units are determined such that a thickness distribution of the thin film on the at least one substrate based on a position of one of said power supply units complements a thickness distribution of the thin film on the at least one substrate based on a position of an adjacent one of said power supply units.

9. A sputtering apparatus as claimed in claim 7 or 8, further comprising conductors disposed in surface contact with said at least one cathode along the direction perpendicular to the predetermined direction, and wherein said power supply units are disposed so as to supply the sputtering electrical power to said at least one cathode via said conductors.

10. A sputtering apparatus as claimed in any one of claims 7 through 9, wherein at least two said cathodes are disposed along the predetermined direction, and wherein one of said power supply units is connected to one of said cathodes and another one of said power supply units is connected to another one of said cathodes.
